(19) United States
(12) Patent Application Publication
(10) Pub. No.: US 2024/0339441 A1
(43) Pub. Date: Oct. 10, 2024

(54) ULTRA-DENSE MICRO-LED AND MICROLENS ARRAYS

(71) Applicant: Tectus Corporation, Saratoga, CA (US)

(72) Inventor: Brian Elliot Lemoff, Morgan Hill, CA (US)

(21) Appl. No.: 18/633,318

(22) Filed: Apr. 11, 2024

Related U.S. Application Data
(63) Continuation of application No. PCT/US2024/023127, filed on Apr. 4, 2024.
(60) Provisional application No. 63/494,445, filed on Apr. 5, 2023.

(51) Int. Cl. H01L 25/075; G02B 3/00; H01L 25/16; H01L 33/58

(52) U.S. Cl. CPC H01L 25/0753; G02B 3/0037; H01L 25/167; H01L 33/58

(57) ABSTRACT

In micro-LED displays, emitters may be arranged to form an array of pixels. Examples of emitters include a micro-LED alone, or a combination of a micro-LED and a color converter. The color converter may be based on quantum dots or other quantum confined nanostructures. Each emitter is served by a corresponding microlens. Rather than using microlenses that fully overlap so that there are no areas of the display devoid of microlenses, optical performance may be increased by using smaller microlenses that partially overlap with each other but which do not cover the entire area of the display.

### CROSS-REFERENCE TO RELATED APPLICATION(S)

This application is a continuation of International Application No. PCT/US24/23127, “Ultra-dense micro-LED array with partially overlapping microlenses,” filed Apr. 4, 2024; which claims priority under 35 U.S.C. § 119 (e) to U.S. Provisional Patent Application Ser. No. 63/494,445, “Ultra-dense micro-LED and microlens arrays,” filed Apr. 5, 2023. The subject matter of all of the foregoing is incorporated herein by reference in its entirety.

### BACKGROUND

### 1. Technical Field

This disclosure relates generally to microdisplays, and more particularly to microlenses on such microdisplays.

### 2. Description of Related Art

Ultra-dense micro-LED arrays are the basis of microdisplays featuring very small pixels arranged on a very small pixel pitch. These microdisplays may use emitters as small as 0.9 um (microns) and have as many as 14,000 emitters per inch, for example. Usually, “ultra-dense” means that the light-emitting area of individual emitters is smaller than 5 um and/or the emitter pitch is also less than 5 um.

Light emitted by micro-LEDs, and especially light subsequently converted to another color (e.g. in a quantum dot color converter), has a broad angular distribution. It may even approach a Lambertian distribution. It is important to collect the emitted light.

### BRIEF DESCRIPTION OF THE DRAWINGS

Embodiments of the disclosure have other advantages and features which will be more readily apparent from the following detailed description and the appended claims, when taken in conjunction with the examples in the accompanying drawings, in which:

FIGS. 1A and 1B are perspective cross sectional views, respectively, of a 3×3 section of a microdisplay with a microlens array.

FIGS. 2A and 2B are cross sectional views of light emitted from a microdisplay without and with microlenses, respectively.

FIG. 3A is a plan view of a 3×3 array of emitters in a monochrome array.

FIGS. 3B-3D are each plan views and cross sectional views of a 3×3 array of emitters using different sizes of microlenses.

FIG. 4 is a set of graphs of boost as a function of microlens diameter, for different emitter diameters.

FIG. 5A shows rays radiating from an emitter to the edge of three different size microlenses.

FIG. 5B shows rays radiating from the center (point C) and the edge (point E) of the emitter for three different size microlenses.

FIG. 6 is a plan view of emitters and microlenses in a two color array.

FIG. 7 is a plan view of emitters and microlenses in another two color array.

FIG. 8 is a plan view of emitters and microlenses in a three color array.

FIG. 9 is a plan view of emitters and microlenses in a hexagonal array.

FIGS. 10A and 10B are plan and cross sectional views, respectively, of microlenses and emitters in an array.

FIG. 11 is a plan view of emitters and microlenses in an array.

### DETAILED DESCRIPTION OF THE PREFERRED EMBODIMENTS

The figures and the following description relate to preferred embodiments by way of illustration only. It should be noted that from the following discussion, alternative embodiments of the structures and methods disclosed herein will be readily recognized as viable alternatives that may be employed without departing from the principles of what is claimed.

This disclosure relates to ultra-dense micro-LED arrays with partially overlapping microlenses. Microlens arrays make micro-LED displays more efficient by compressing emitted light into desirable acceptance angles. Without a microlens, much of the light emitted by a microdisplay pixel may be unusable because it exits the emitter at angles too far away from normal. For example, augmented reality (AR) glasses and goggles use light directed into a specified acceptance angle, which may be as narrow as 30 to 40 degrees, full width. Light outside this acceptance cone will not be coupled into the rest of the system and will be wasted.

In micro-LED displays, uniformly-sized emitters may be arranged on an evenly spaced, rectangular grid. Examples of emitters include a micro-LED alone, or a combination of a micro-LED and a color converter. The color converter may be based on quantum dots or other quantum confined nanostructures. Each emitter is served by a corresponding microlens. The microlenses may overlap so that there are no areas of the display devoid of microlenses. Surprisingly, this approach is not optimal. Rather, as described herein, optical performance may be increased by using smaller microlenses that partially overlap with each other but which do not cover the entire area of the display.

Ultra-dense micro-LED and microlens arrays are designed to maximize light directed into useful acceptance angles and compensate for differences in efficiency among red, green and blue emitters. The amount of red, green, or blue light emitted by a pixel in a microdisplay for a given current input may depend both on the efficiency of a micro-LED and the efficiency of color conversion, for example in a layer of quantum dots.

In ultra-dense micro-LED and microlens arrays, the sizes of microlenses serving either individual emitters or groups of emitters may be different from those of conventional designs. Adjacent microlenses may partially overlap, yet not fill all of the space between emitters. Microlenses in an array may not all be the same size. Furthermore, emitters of different colors may have different sizes.

The “boost” of a microlens array is defined as the ratio of (a) the optical power coupled into a specified acceptance cone by emitters in a microdisplay with the microlens array to (b) the power coupled into the same acceptance cone without the microlens array. For example, if the boost of a certain microlens array design is 2.7, then combining the microlenses with the emitters results in 2.7 times as much light being coupled into the acceptance conc.

The small size (e.g. 0.5-2.0 um) of the emitters enables the new kinds of microlens arrays described here. If the emitters were not so small, then designs in which the size of the microlens is different from conventional would not produce displays with high enough resolution for many applications. Or the display would be too large to fit in AR glasses and other applications.

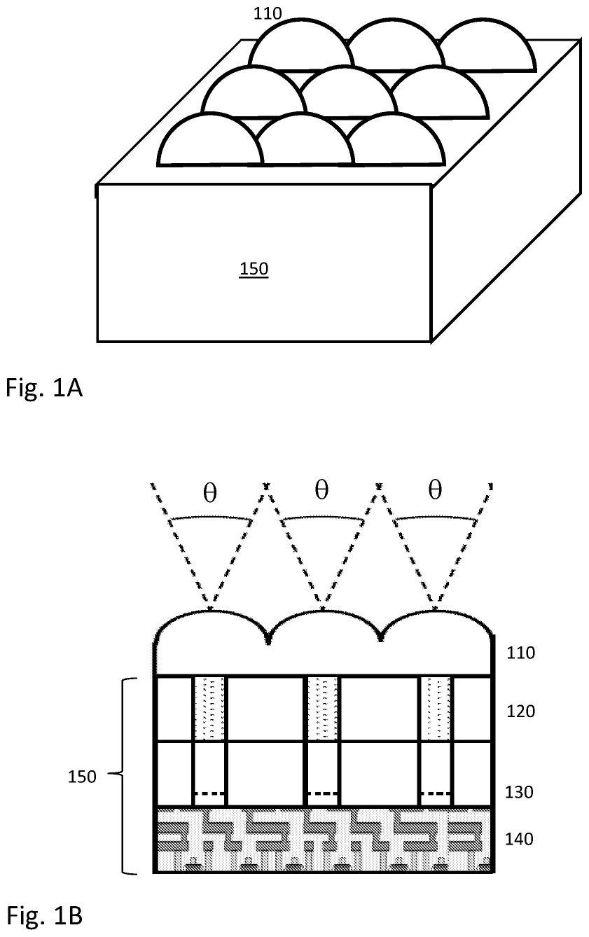

FIGS. 1A and 1B are a perspective view and cross sectional view of a 3×3 section from a microdisplay with partially overlapping microlenses. The microlens array 110 includes small, clear sections of spheres arranged in a regular pattern. In FIG. 1 the microlenses have spherical curvature and the microlenses are overlapping but not all of the display area is covered by microlenses. In other designs, the microlenses may have different shapes and curvatures. FIG. 1 shows only a 3×3 array. In real displays there may be several million microlenses and emitters or more, depending on how many pixels the display has. For example, 4K UHD resolution has 3840×2160 (8,294,400) color pixels, each of which may have red, green and blue emitters, each with its own microlens. For some applications, there may also be far fewer microlenses and emitters, for example 1,000 of each in low resolution monochrome displays. Microlenses may be made of plastic or glass. The perspective view of FIG. 1A shows the microlens array 110 and a semiconductor die 150 with the emitters and driver circuitry.

FIG. 1B is a cross sectional view of the display. From bottom to top, the semiconductor die 150 includes driver circuitry 140, micro-LEDs 130 and quantum dot color conversion materials 120. In this example, the micro-LEDs 130 are all the same color. They may be gallium nitride LEDs. The color conversion materials 120 convert the light from the micro-LEDs 130 to different colors. The micro-LEDs 130 and color conversion materials 120 form the emitters of FIG. 1B. The different color emitters may be arranged into color pixels. The driver circuitry 140 controls the brightness of individual micro-LEDs, which in turn controls the brightness and color of each color pixel. There is one microlens 110 for each emitter. The microlens collects light from the emitter and couples it into the acceptance cone (full angle θ) for the rest of the system.

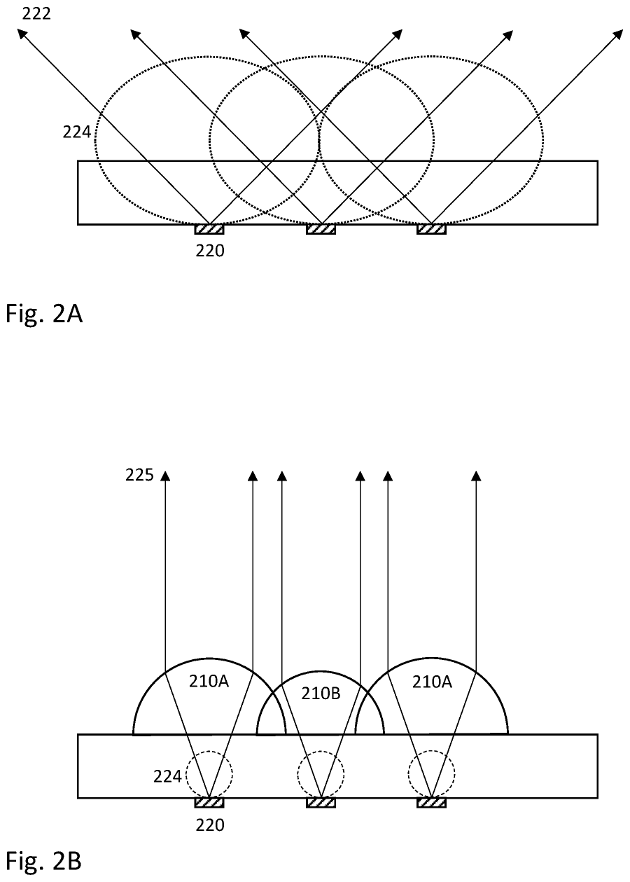

FIGS. 2A and 2B show the effect of microlenses on light collection. In the following disclosure, the emitters are represented as flat two-dimensional areas, sometimes marked by diagonal cross-hatching. FIG. 2A is a cross sectional view of light emitted from a microdisplay without microlenses. FIG. 2A shows three emitters 220. Light is emitted over a wide range of angles as suggested by the rays 222 and the schematic intensity polar diagrams 224 in the figure. The radiation pattern may approach a Lambertian distribution in some cases. If light emitted from the display is coupled into a downstream optical system (e.g. projection optics), then any light that propagates outside the acceptance cone of the downstream optics is lost. Lost light reduces the overall efficiency of the system which can be a major concern for battery operated displays. A 10% increase in efficiency gives 10% longer battery life, all other things being equal.

FIG. 2B is a cross sectional view of light emitted from a microdisplay with microlenses 210A-B. The microlenses 210 collimate the emitted light into a narrower range of angles, as indicated by rays 225, so that more light falls within the acceptance cone of any downstream optical systems. In FIG. 2B, different microlenses 210A and 210B are used for different emitters. As mentioned above, the improvement in system performance with microlenses (FIG. 2B) versus without microlenses (FIG. 2A) is quantified as the “boost” of the microlens array. The “boost” of a microlens array is defined as the ratio of (a) the optical power coupled into a specified acceptance cone by emitters in a microdisplay with the microlens array to (b) the power coupled into the same acceptance cone without the microlens array.

Now first consider microlens arrays for a monochrome display. For purposes of simplification, assume that all the emitters in the display are the same and the emitters are arranged in a square array characterized by a pitch. For square arrays, the pitch in the x and y directions is the same. Each emitter is a separately controllable pixel of the display. The pitch from one emitter to the next adjacent emitter is the emitter pitch, which in this example is also the pixel pitch. Each emitter is served by a corresponding microlens, and the microlenses are also arranged in a square array with the same pitch. Each microlens is centered on the corresponding emitter. The light-emitting area of the emitters may be circular, square, square with rounded corners or other shapes. The size of emitters may be characterized by their diameter, width or, more generally, maximum width.

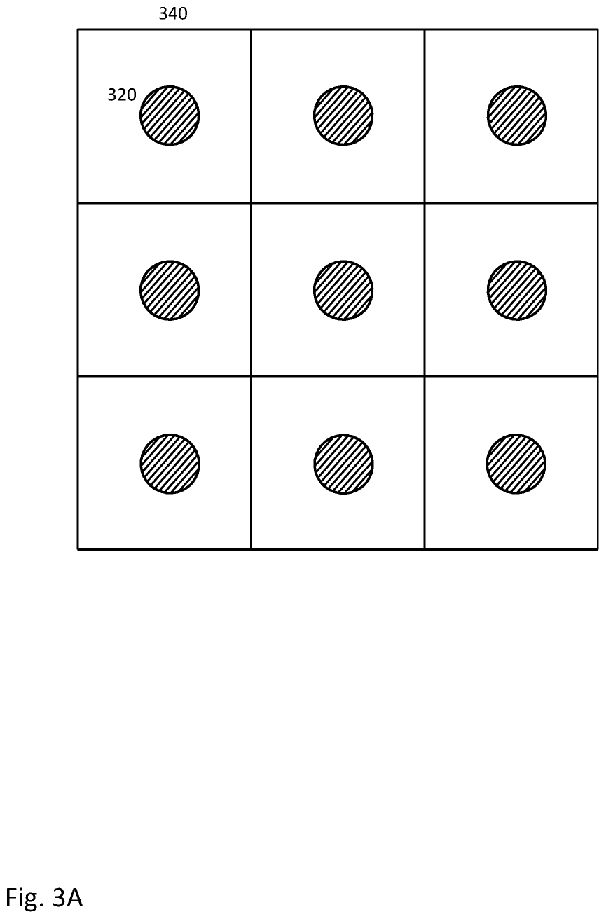

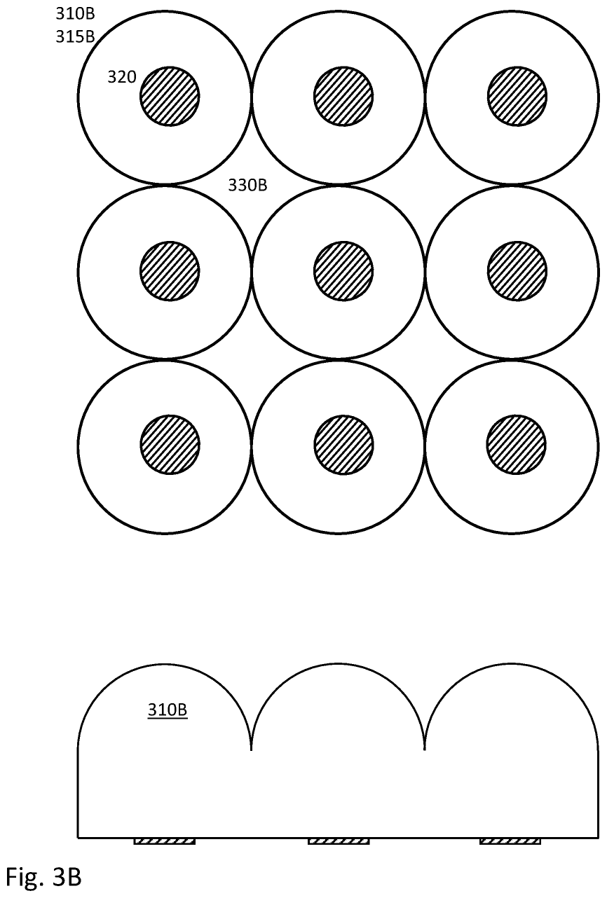

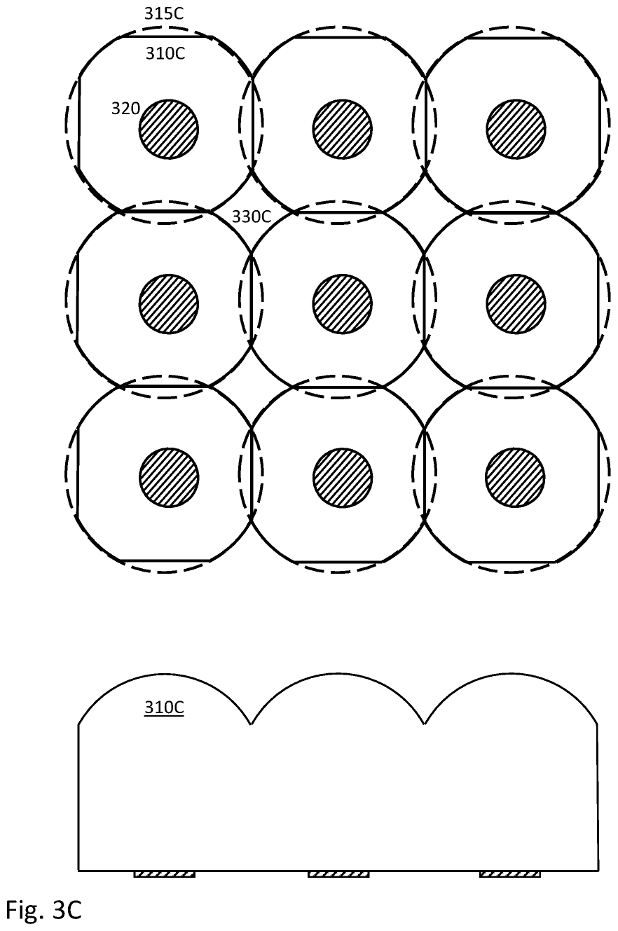

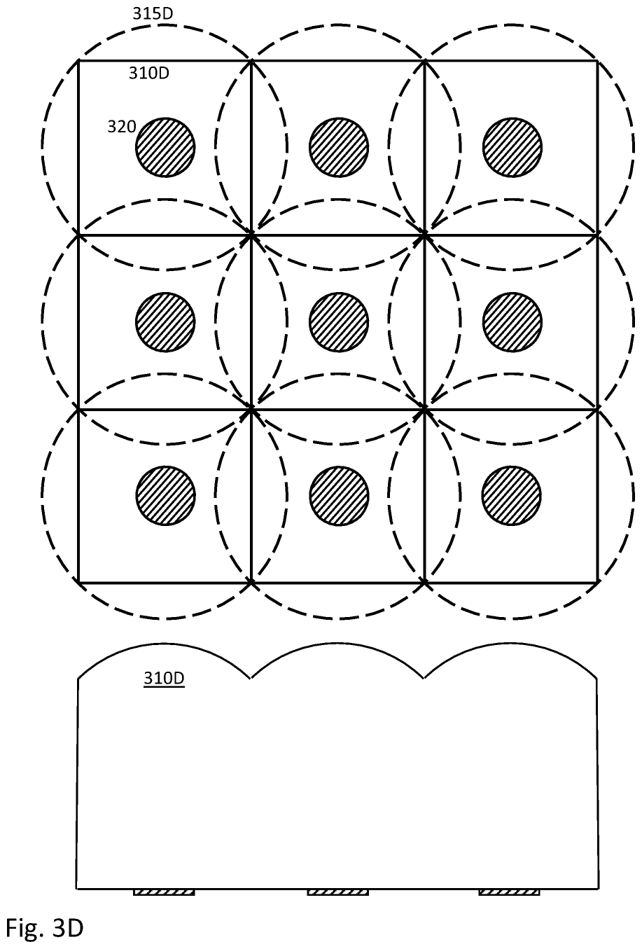

FIG. 3A is a plan view of a 3×3 array of emitters 320 in a monochrome array. In this example, the emitters are circular in light-emitting area, and the circular emitters are arranged in a square array, with the following specifications:
emitter diameter: 1 um
emitter pitch: 3 um
pixel pitch: 3 um
   The square pixels 340 are shown by the solid lines. The square pixels are 3 um×3 um, and this limits the size of the microlenses, assuming that the microlenses are all the same. If a microlens is larger than 3 um×3 um, it will overlap with the microlens from an adjacent pixel and will be truncated to a maximum size of 3 um×3 um.

FIGS. 3B-3D show a range of different size microlenses, which are also microlenses with different curvatures. In this example, the microlenses have spherical curvature. The surface of the microlens is part of a sphere. Each figure includes a plan view of the 3×3 array, and a cross section through the middle row. In the plan view, the dashed circle shows the area that would be covered by a hemispherical microlens, if there were no neighboring microlenses. The radius of the dashed circle is also the radius of curvature of the lens. The solid lines show the actual area covered by each microlens, which is limited by overlap with its neighbors. The microlenses are increasing in size and radius of curvature from FIG. 3B to 3D.

Consider first the two extremes, as shown in FIGS. 3B and 3D. In FIG. 3B, the microlenses 310B are just touching but not overlapping. In FIG. 3B, the diameter of the microlenses is 3 um, which is the same as the pixel pitch. As a result, the microlenses do not overlap and each microlens is a full hemisphere, as shown in the cross section view. In the plan view, the dashed circle 315B showing the circular base of the hemispherical microlens cannot be seen because it coincides with the solid line 310B showing the edge of the actual microlens. This design may be referred to as non-overlapping. In the non-overlapping configuration, the microlenses do not cover the entire area of the arrays. There are gaps 330B between the microlenses. The dashed circle 315B is the largest circle that inscribes the square pixels 340 (from FIG. 3A). Thus, the radius of curvature of these lenses is equal to the radius of the inscribing circle 315B, which in this case is 1.5 um or half the width of the square pixels.

In FIG. 3D, the microlenses 310D are just large enough to cover the entire area of the array. There are no gaps between microlenses. The diameter of the microlenses is 3\sqrt{2} (i.e. about 4.24 um). In this situation, the microlenses overlap quite a bit with their row and column neighbors (nearest neighbors) and just touch but do not overlap with their diagonal neighbors (next nearest neighbors). The dashed circles 315D show the area extent of the full hemispherical microlens. These microlenses are overlapping, so the actual area covered by each microlens is shown by the solid square 310D. The microlenses in FIG. 3D are not flat. On the contrary, they are square sections of spherical surfaces. When the lens diameter is v2 times the emitter pitch, as is the case in FIG. 3D, there is no empty area. There is no place that is not covered by a microlens. This design may be referred to as fully overlapping. The dashed circle 315D is the smallest circle that circumscribes the square pixels 340. The radius of curvature of these lenses is equal to the radius of the circumscribing circle 315D, which in this case is approximately 2.12 um or half the diagonal of the square pixels.

One might think that the fully overlapping configuration of FIG. 3D is best in terms of delivering light to downstream optics, but that is not always correct. The partially overlapping configuration shown in FIG. 3C may be better for certain applications.

In FIG. 3C, the lens diameter is between the 3 um of FIG. 3B and the 4.24 um of FIG. 3D. Here, it is 3.4 um, or 1.133 times the emitter pitch. In addition, the lens radius of curvature is between the 1.5 um of FIG. 3B and the 2.12 um of FIG. 3D. Here, it is 1.7 um. The microlenses 310C overlap with their row and column (i.e. nearest) neighbors, but do not overlap with their diagonal (i.e. next nearest) neighbors. There is a gap 330C between microlenses. The area covered by each individual microlens has a border that is curvilinear. The border is a circular arc where the individual microlens is not overlapping with another microlens, and it is linear where there is overlap. This design may be referred to as partially overlapping. The radius of curvature of the lens is the radius of circle 315C, which is between the inscribing circle 315B and the circumscribing circle 315D. Base circle 315C overlaps both the interior and the exterior of the square pixel 340. The partially overlapping configuration shown in FIG. 3C has higher boost than the non-overlapping and fully overlapping designs shown in FIGS. 3B and 3D. Making the microlenses bigger and filling in the gap between diagonally adjacent lenses (FIG. 3D) reduces the boost compared to the situation shown in FIG. 3C.

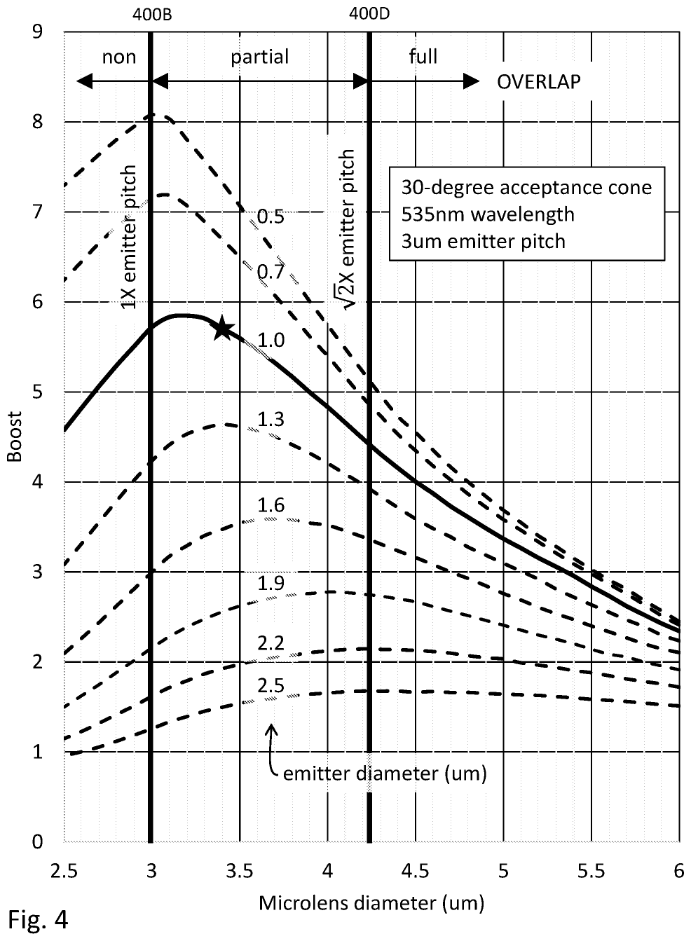

FIG. 4 is a set of graphs of boost as a function of microlens diameter, for different emitter diameters. The emitter diameters range from 0.5 μm to 2.5 um. These graphs use a 3 um emitter pitch, 30 degree acceptance cone and 535 nm wavelength. Consider the solid curve in FIG. 4 which represents boost versus microlens diameter for a 1.0 um diameter emitter, the configuration shown in FIGS. 3A-3D. On this curve, the parameters of FIG. 3C, 1 um emitter diameter, 3 um emitter pitch and 3.4 um lens diameter, are labeled with a star. The boost for this situation is roughly 5.7 and is near the optimum or peak of the curve. A microlens diameter of 3.2 um would give slightly higher boost. A 3.4 um microlens diameter has maximum boost for a 1.3 um emitter diameter.

The vertical line 400B labeled “1× emitter pitch” corresponds to the non-overlapping situation of FIG. 3B, where nearest neighbor microlenses just touch each other but do not overlap. When the microlens diameter is less than the emitter pitch, the microlenses do not touch and there is a gap between them. This region is labeled “non” for “non-overlapping.” The vertical line 400D labeled “\sqrt{2x} emitter pitch” corresponds to the fully overlapping situation of FIG. 3D, where the microlenses cover the entire area of the array. The region to the right of this line is labeled “full” for “fully overlapping.” The region between the “1x” vertical line 400B and the “\sqrt{2x}” vertical line 400D is labeled “partial”, corresponding to the partially overlapping situation of FIG. 3C. There is some overlap of microlenses, but the microlenses do not cover the entire area of the array.

Some trends are apparent from FIG. 4. First, the maximum boost is generally achieved for microlens diameters between 1 and \sqrt{2} times the emitter pitch. For hemispherical lenses, the radius of curvature would be between 1/2 and \sqrt{2}/2 times the emitter pitch. In this partially overlapping region, microlenses overlap their nearest (row, column) neighbors but not their next nearest (diagonal) neighbors for square arrays. Second, for small emitters (e.g. emitter diameter <0.2 times emitter pitch, or emitter diameter <0.6 um in FIG. 4) maximum boost is achieved when the microlens diameter is approximately equal to the emitter pitch, or the radius of curvature is approximately equal to emitter pitch/2. Third, for medium size emitters (e.g. 0.2 times emitter pitch <emitter diameter <0.5 times emitter pitch, or 0.6 um <emitter diameter <1.5 um in FIG. 4) maximum boost is achieved when the microlens diameter is a little larger than the emitter pitch (e.g. 1 times emitter pitch <microlens diameter <1.2 times emitter pitch), or the radius of curvature is a little larger than the emitter pitch/2. This is the partially overlapping region. Fourth, for large emitters (e.g. 0.5 times emitter pitch <emitter size <1 times emitter pitch, or 1.5 um <emitter diameter <3.0 um in FIG. 4) maximum boost is achieved when the microlens diameter and radius of curvature remains in the “partially overlapping” region. However, as the microlens diameter approaches the “fully overlapping” region (\sqrt{2} times emitter pitch), the boost curve flattens and boost decreases slowly in the “fully overlapping” region. These trends are summarized in Table 1:

TABLE 1
Maximum boost trends.

| | Lens diameter for | Lens radius of curvature |
|---|---|---|
| Emitter diameter | maximum boost | for maximum boost |
| (in units of | (in units of | (in units of |
| emitter pitch) | emitter pitch) | emitter pitch) |
| emitter | lens | lens radius of |
| diameter < 0.2 | diameter ~ 1 | curvature ~ 0.5 |
| 0.2 < emitter | 1 < lens | 0.5 < lens radius of |
| diameter < 0.5 | diameter < 1.2 | curvature < 0.6 |
| 0.5 < emitter | 1.2 < lens | 0.6 < lens radius of |
| diameter < 1 | diameter < \sqrt{2} | curvature < \sqrt{2}/2 |

FIG. 4 assumes a 30 degree, full angle, acceptance cone for emitted light. The trends noted above remain the same for a 40 degree acceptance cone, but the boost values are less. For the center row (0.2<emitter diameter <0.5), the lens diameter is between 1× and 1.2× the emitter pitch. At these values, the lenses will cover between 79% and 95% of the area of the array. At 1.1× the emitter pitch, the lenses cover 89% of the area of the array. When emitter diameter=0.5 emitter pitch, the emitters will cover 20% of the area of the array (for square emitters).

It is clear from FIG. 4 that making microlenses large enough to fill the gap between diagonally adjacent lenses leads to less than optimum boost. Maximum boost occurs when lenses overlap nearest neighbors, but not next nearest neighbors, i.e., in the partially overlapping region. For some situations, the boost from a properly designed partially overlapping configuration can be 10% higher than the boost from non-overlapping or fully overlapping designs.

The location of the maximum boost may be thought of as a tradeoff between competing effects. On the one hand, increasing lens diameter improves the factor by which light rays from the emitter are collimated. By the principle of conservation of etendue, d Ω=D·Ω′, where d is the diameter of the emitter and D is the diameter of the lens. 2 is the solid angle subtended by rays leaving the emitter and Q′ is the solid angle subtended by rays after passing through the lens. D/d is the factor by which the solid angular spread of rays is reduced by the lens. The collimating effect of the lens improves coupling into a specified acceptance angle, which increases boost.

On the other hand, as lens diameter increases in the “partial overlap” region (lens diameter between 1 and \sqrt{2} times the emitter pitch), parts of the edge of the lens are truncated. A truncated lens does not affect light rays that pass outside its edges. A larger lens collects light from a smaller solid angle as the edge of the lens is cut off where it overlaps its neighbors.

Maximum boost occurs when the beneficial effect of larger lens diameter (better collimation) is balanced by the deleterious effect of larger lens diameter (less light collected because of edge truncation).

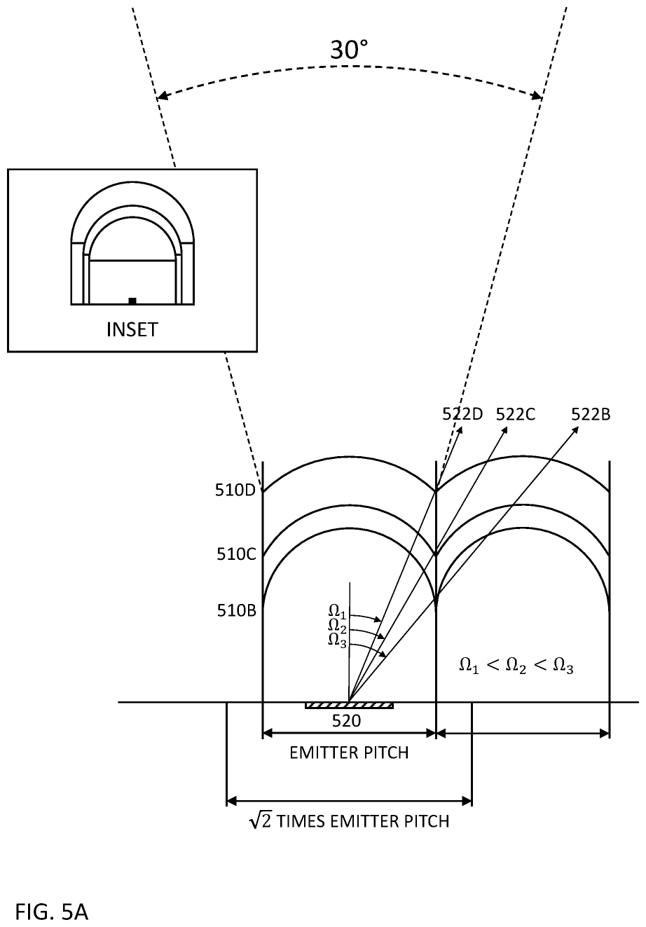

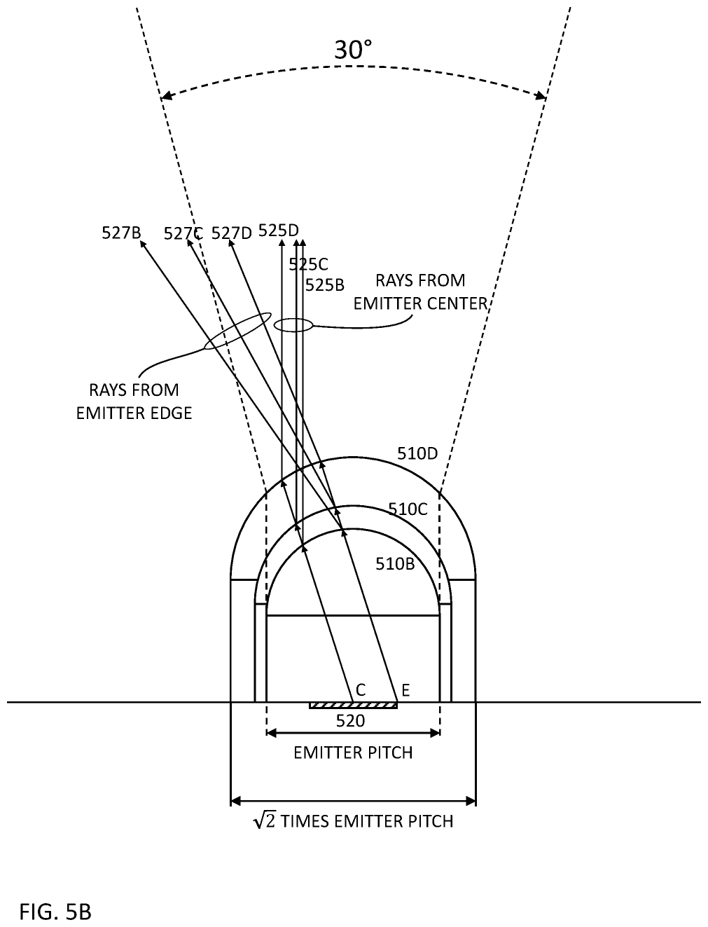

FIGS. 5A and 5B illustrate these points. FIG. 5A shows that boost decreases if microlenses in an array are too big. On the other hand, FIG. 5B shows that boost decreases if the microlenses are too small.

These effects are related to the micro-LED emitters being placed close together (small emitter pitch), the size of the emitters being an appreciable fraction of the emitter pitch, and boost being a figure of merit based on focusing light within a specified acceptance cone.

In this example the emitter pitch is 3 um in both the row and column directions of a square array. The emitter diameter is half the emitter pitch. Consider lenses of 3 um, 3.4 um and 4.24 um diameter, which are the situations show in FIGS. 3A-3C. The 3.0 um lenses are tangent to their nearest (row and column) neighbors and far from their next nearest (diagonal) neighbors. The 3.4 um lenses overlap their nearest neighbors, but not their next nearest neighbors. The 4.24 um (i.e. v2 times the emitter pitch) lenses overlap their nearest neighbors and touch their next nearest neighbors. They do not leave any open gaps in the array.

The inset in FIG. 5A shows that as lenses are made with larger diameters, they are also positioned farther away from the emitter because the focal length increases. The emitter is located at the focus of the microlens. The focal length of a hemispherical lens with refractive index 1.5 is about twice the radius of the lens. If the lens is a full hemisphere, then the spacer between the lens and the emitter will be approximately one lens radius thick or approximately a same height as the lens.

FIG. 5A shows rays radiating from an emitter to the edge of three different size microlenses. The microlenses 510B, 510C, 510D are 3 um, 3.4 um and 4.24 um diameter, but the larger lenses are truncated by the pixel size so they are not full hemispheres. The rays 522B, 522C, 522D are inclined away from normal as far as they can be before being cut off at the boundary between a lens 510 and its nearest neighbor lens. The lenses 510D, 510C, 510B subtend angles Ω₁<Ω₂<Ω₃. Under these conditions, smaller lenses (e.g, 510B) collect light from larger solid angles (e.g., Ω₃). Equivalently, for a fixed emitter pitch, larger, more-overlapping lenses subtend smaller solid angles, so less light is collected and refracted by the lens surface. Thus the total light emitted from the lens surface is smaller for larger lenses. This effect favors smaller lenses.

FIG. 5B shows rays radiating from the center (point C) and the edge (point E) of the emitter for three different size microlenses. Rays 525B, 525C, 525D are from the center and refracted by lenses 510B, 510C, 510D. They are refracted to the vertical direction in the figure. Rays 527B, 527C, 527D from the edge, however, are refracted at angles away from vertical and may not fall within a finite acceptance cone. These rays 572, when refracted by smaller lenses, are refracted at larger angles, leading to lower boost.

For yet another explanation of the same effect, consider two rays hitting the same point, P, on the lens surface. One ray originates from center point C and, by design of the lens, is refracted in the vertical direction. The second ray originates from edge point E. The refracted angle of this ray, away from vertical, increases as the angular difference between the two rays (angle EPC) increases. Assuming the distance from the emitter to the lens surface is the focal length of the lens, the angle EPC decreases as the lens becomes larger and the emitted divergence angle also decreases, leading to more light falling within the acceptance cone. This effect favors larger lenses.

The tradeoff between the two effects shown in FIGS. 5A and 5B determines the design with the highest boost.

Color displays may use different architectures. For example, the rectangular arrays of FIG. 3 may also be organized into color pixels where each color pixel has four emitters and one color is repeated; for example, red, red, green and blue.

Alternatively, some displays produce a color output by combining light from a red display with light from a green-blue display. The red display in such a system may follow the design principles for monochrome displays as discussed above. The green-blue (or any two-color display) may follow more elaborate designs. For example, microlenses serving green emitters may not be the same size as those serving blue emitters.

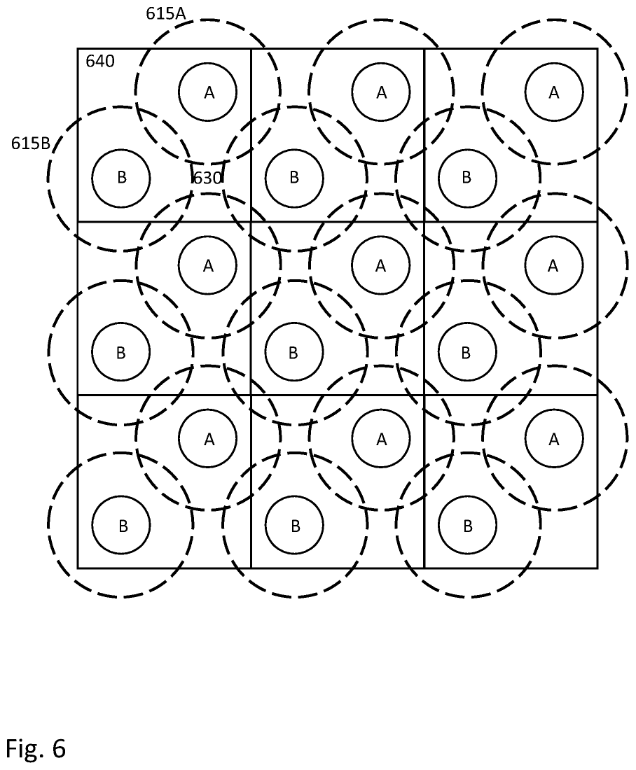

FIG. 6 is a plan view of emitters and microlenses in a two color array. In the example of FIG. 6, all the emitters are the same size. They are labelled as A or B to indicate the color. However, that is not a general requirement. In some displays, emitters of different colors may be different sizes. The diameter of each emitter in FIG. 6 is 1 um. The emitter pitch along diagonals (i.e. the pitch with nearest neighbors) is 2.12 um. The emitter pitch along rows and columns (i.e. the pitch with next nearest neighbors) is 3 μm. The emitters are paired to form color pixels as indicated by the squares 640. The squares are shown purely to illustrate the color pixel grouping. In each color pixel, one emitter A emits light of one color while the other emitter B emits light of a different color. In FIG. 6, the microlenses are indicated by the dashed circles 615A and 615B. These would be the circular bases of the hemispherical microlenses, if they did not overlap. The diameter is 2.5 um for each microlens. Nearest neighbor microlenses overlap, but next nearest neighbor microlenses do not overlap. The area covered by the microlenses is truncated from the circles 615A,B due to the overlap. For clarity, the actual area covered by each microlens is not shown in FIG. 6. The microlenses do not cover the entire area of the array, leaving gaps 630.

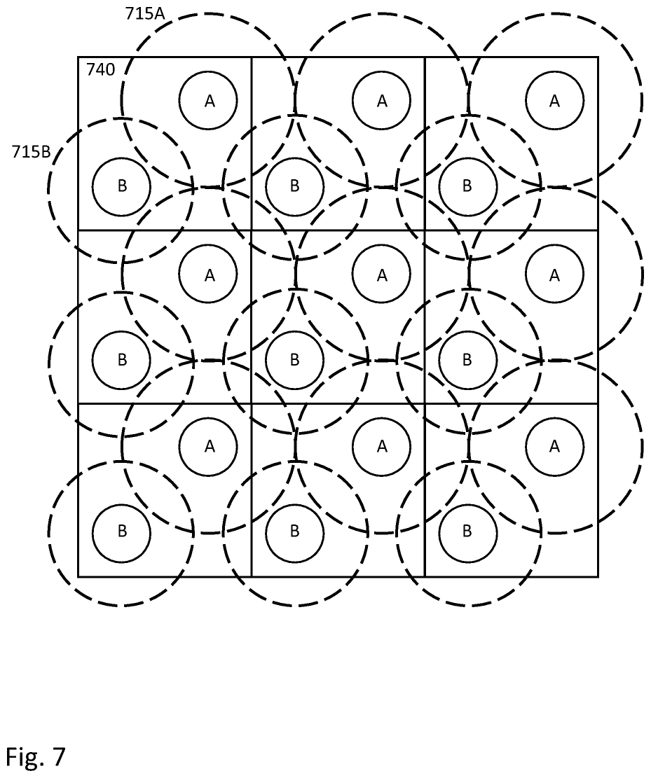

FIG. 7 is a plan view of emitters and microlenses in another two color array. FIG. 7 shows the same situation as FIG. 6, but there are two different size microlenses indicated by circles 715A, 715B. Each color pixel 740, containing for example one green and one blue emitter, has a 2.5 um diameter lens 710B serving one emitter B and a 3 um diameter lens 710A serving the other emitter A. Having different sized microlenses may be advantageous when the different color emitters have unequal efficiency converting electric current to light, as is often the case. A less efficient emitter may be paired with a larger microlens, for example.

Up to the point where nearest neighbor microlenses overlap, it is always better to make the lenses as large as possible to increase boost. Once the microlenses overlap, as in FIG. 7, for example, then it may be better to couple more electrically efficient emitters with smaller microlenses and less electrically efficient microlenses with larger microlenses. When the emitters and microlenses are laid out as in FIGS. 6-7, on two square grids shifted along a diagonal, then the boost optimizations discussed above may apply.

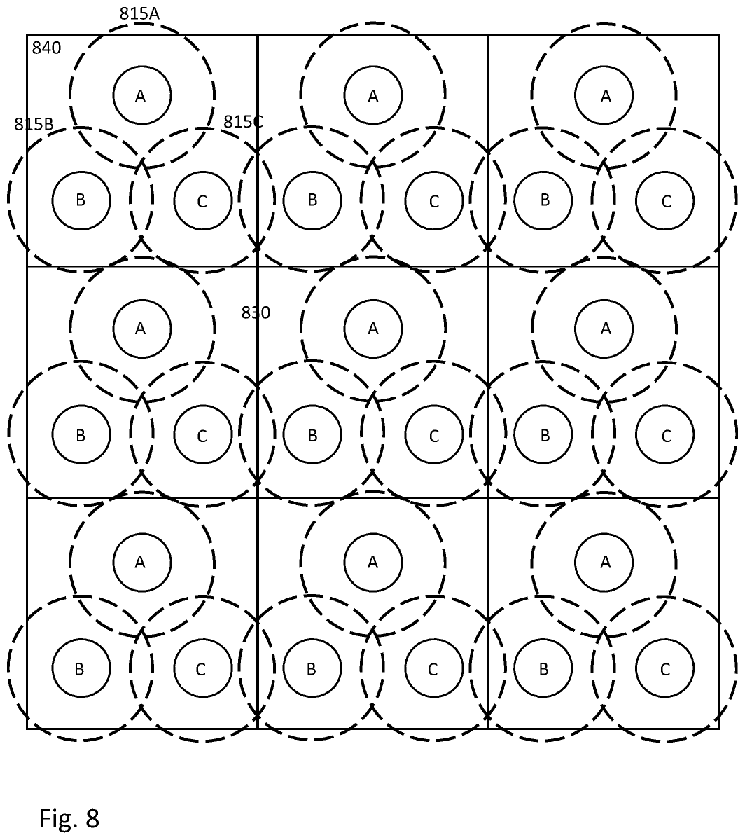

FIG. 8 is a plan view of emitters and microlenses in a three color array. A three-color display is often a red-green-blue display that can show a wide variety of colors depending on the relative intensity of red, green and blue subpixels. In FIG. 8, each emitter has a diameter of 1 um. However, that is not a general requirement. In some displays, emitters of different colors may be different sizes. As in FIGS. 6 and 7, color pixels are indicated by squares 840, but the squares do not correspond to any physical structure. Each color pixel includes three emitters A, B, C arranged as an equilateral triangle, and the center-to-center distance between emitters within a color pixel is 2.1 um. Each emitter A, B, C is served by a corresponding microlens as indicated by the dashed circles 815A, 815B, 815C. The lens diameters are all 2.5 um. However, that is not a general requirement. In some displays, microlenses for different color emitters may be different sizes. Or there may be one microlens size for two colors and a different size for the third color. In FIG. 8, the pixel pitch (the width of pixel 840) is 4 um. This is also referred to as the color pixel pitch, since a color pixel is formed from red, green and blue subpixels. There are gaps 830 between some of the microlenses so the entire display area is not covered in microlenses.

The boost optimization principles discussed above apply to the situation of FIG. 8 as well. There are more parameters to consider however. In addition to lens diameter, emitter diameter and emitter pitch, subpixel pitch and subpixel geometry are additional design parameters.

So far only rectangular unit-cell arrays have been considered. However, a hexagonal layout is also possible.

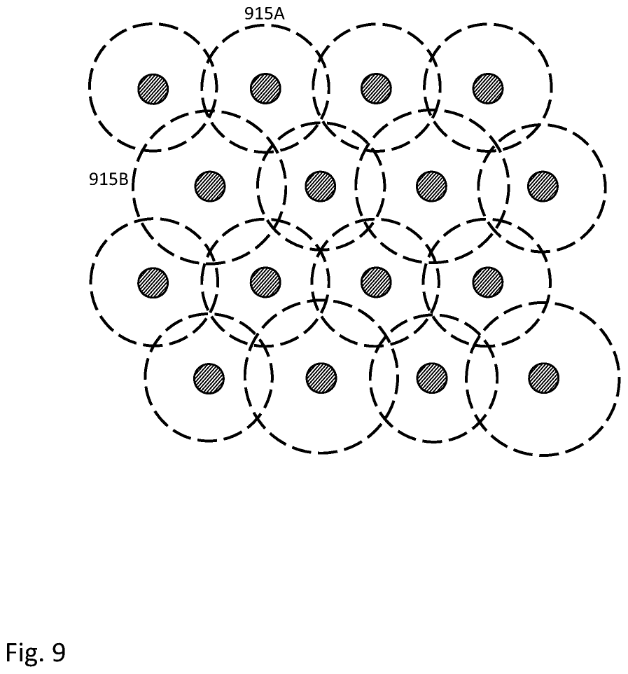

FIG. 9 is a plan view of emitters and microlenses in a hexagonal array. The emitters are cross-hatched. The microlenses are indicated by the dashed circles. In a hexagonal array, not all microlenses need to be the same size. Different sizes may be chosen for microlenses serving different color emitters, for example. The optimum lens size and overlap criteria may also be different compared to the rectangular cases discussed above. FIG. 9 shows microlenses of two different sizes 915A,B.

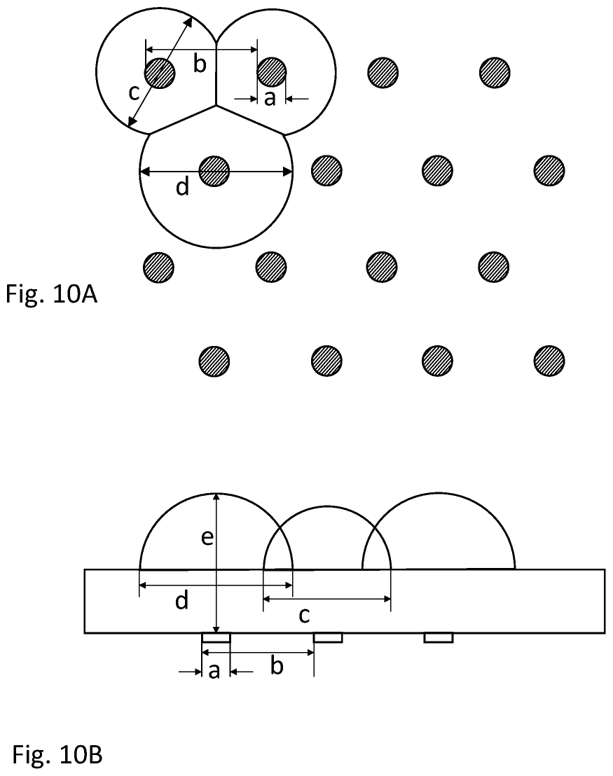

FIGS. 10A and 10B are plan and cross sectional views, respectively, of microlenses and emitters in an array. In these figures, various characteristic dimensions of a microlens array are shown. Dimension ‘a’ is the size of a light emitter such as a micro-LED or a micro-LED and its associated color converter. Dimension ‘b’ is the emitter pitch, or distance from the edge of one emitter to the corresponding edge of the adjacent emitter in the array. Dimensions ‘c’ and ‘d’ are diameters of microlenses. Not every microlens in an array necessarily has the same diameter. There may be one, two or three different diameters found among the microlenses of an array. Dimension ‘e’ is the thickness of the microlens array. In many of the examples discussed above d≈e. In FIG. 10, adjacent microlenses overlap somewhat. The overlap causes the shape of the microlenses as seen in FIG. 10A to be non-circular. The curved edge of a microlens is truncated to a line segment where the microlens overlaps with a neighbor.

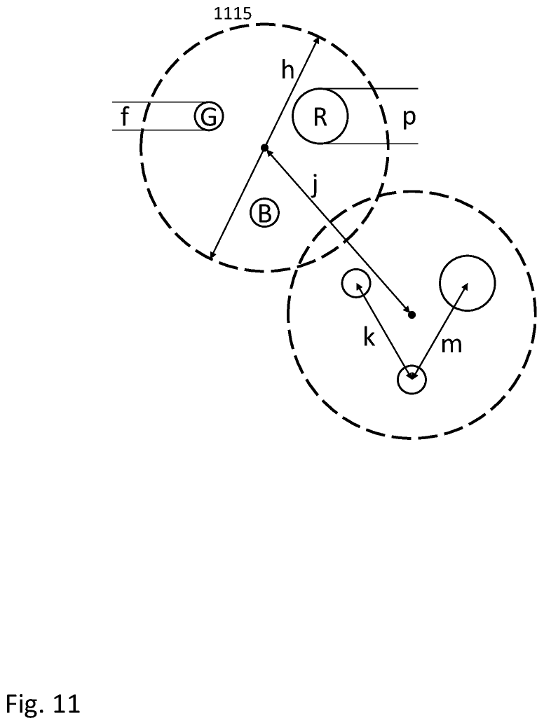

FIG. 11 is a plan view of emitters and microlenses in an array. In this example, three emitters R,G,B of different colors make up each color pixel. The red (R) emitters are larger, and the blue (B) and green (G) emitters are the same size and smaller. In FIG. 11, one microlens defined by the circular base 1115 serves each color pixel. FIG. 11 illustrates the following parameters, which may be selected when designing a microlens array:
diameter of emitters: f, p
spacing of emitters: k, m
diameter of microlens: h
pixel pitch: j
color of emitters: R, G, B

The microlens arrays discussed herein may be made by imprinting curable UV resins on a micro-LED array. After a curable UV resin is applied to a micro-LED wafer, a stamp forms the resin into microlenses. The resin is cured via exposure to ultraviolet light and then the stamp is removed. Alternatively, microlens arrays may be formed by etching and grayscale photoresist techniques. Photoresist reflow may also be useful for forming microlenses which do not touch their neighbors.

So far, we have assumed that each microlens is aligned with its corresponding emitter. That is not a requirement, however, and intentional misalignment is desirable in some cases. Emitters (with dimension ‘a’ in FIG. 10) need not lie directly under the center of their microlenses (with dimension ‘c’ and ‘d’ in FIG. 10). For example, if the emitters and microlenses are increasingly offset as a function of distance from the center of a large array, then the misalignment steers the angle of collimated light from each microlens as if a large focusing lens had been placed over the entire array. This effect can be used to aim the light from individual emitters toward the center of an acceptance aperture rather than normal to the plane of the emitter array.

Although the detailed description contains many specifics, these should not be construed as limiting the scope of the invention but merely as illustrating different examples. It should be appreciated that the scope of the disclosure includes other embodiments not discussed in detail above. Various other modifications, changes and variations which will be apparent to those skilled in the art may be made in the arrangement, operation and details of the method and apparatus disclosed herein without departing from the spirit and scope as defined in the appended claims. Therefore, the scope of the invention should be determined by the appended claims and their legal equivalents.

What is claimed is:

1. A microdisplay comprising:
at least 1,000 emitters on a semiconductor die that produce light, the emitters arranged as an array of controllable pixels; and
at least 1,000 microlenses positioned to collect the light produced by the emitters, wherein the microlenses are overlapping but do not cover an entire area of the array of pixels.

2. The microdisplay of claim 1, wherein each microlens overlaps with its nearest neighbor microlenses.

3. The microdisplay of claim 2, wherein each microlens overlaps only with its nearest neighbor microlenses.

4. The microdisplay of claim 1, wherein the microlenses cover between 79% and 95% of the area of the array.

5. The microdisplay of claim 1, wherein the emitters are arranged in a square array characterized by an emitter pitch, and the microlenses have a spherical curvature with a diameter that is between 1× and 1.2× the emitter pitch.

6. The microdisplay of claim 1, wherein the emitters are arranged in a square array characterized by an emitter pitch, and the microlenses have a spherical curvature with a radius of curvature that is between 0.5× and 0.6× the emitter pitch.

7. The microdisplay of claim 1, wherein the light-emitting areas of all the emitters covers at least 20% of the area of the array.

8. The microdisplay of claim 1, wherein the emitters are arranged in a square array characterized by an emitter pitch, and a maximum width of the emitters is at least 50% of the emitter pitch.

9. The microdisplay claim 1, wherein the microlenses couple the collected light into an acceptance angle of between 30 and 40 degrees full width.

10. The microdisplay of claim 1, wherein each emitter has a light-emitting area of not more than 10 um².

11. The microdisplay of claim 1, wherein each emitter has a light-emitting area with a maximum width of not more than 3 um.

12. The microdisplay of claim 1, wherein the total area of the array is not more than 25 um² per emitter.

13. The microdisplay of claim 1, wherein each pixel has a maximum width of not more than 5 um.

14. The microdisplay of claim 1, wherein each microlens has a boost of at least 3.

15. The microdisplay of claim 1, wherein each microlens has a boost that is at least 10% higher than a boost produced by a set of non-overlapping microlenses and is at least 10% higher than a boost produced by a set of microlenses that cover the entire area of the array.

16. The microdisplay of claim 1, wherein the microlenses have a spherical curvature.

17. The microdisplay of claim 1, wherein the microlenses includes microlenses of different curvatures.

18. The microdisplay of claim 1, wherein individual microlenses cover areas with curvilinear borders.

19. The microdisplay of claim 18, wherein the borders are linear where microlenses overlap and circular where microlenses are not overlapping.

20. The microdisplay of claim 1, wherein different emitters produce visible light of different colors.

21. The microdisplay of claim 20, wherein the emitters are arranged into an array of color pixels, with a same pattern of different color emitters within each color pixel.

22. The microdisplay of claim 21, wherein the pattern of different color emitters within each color pixel is a non-rectangular pattern.

23. The microdisplay of claim 20, wherein a plurality of the emitters include color conversion materials.

24. The microdisplay of claim 20, wherein microlenses of different designs are used to collect light from different color emitters.

25. The microdisplay of claim 20, wherein microlenses of different curvature are used to collect light from different color emitters.

26. The microdisplay of claim 1, wherein the emitters include GaN micro-LEDs.

27. A microdisplay comprising:
a plurality of micro-LED emitters on a semiconductor die that produce visible light of different colors, the micro-LED emitters arranged into an array of controllable color pixels;
a transparent spacer layer positioned above the micro-LED emitters; and
a set of spherical microlenses supported by the spacer layer, wherein there is a one-to-one correspondence between microlenses and micro-LED emitters, each microlens is positioned to collect the visible light produced by the corresponding micro-LED emitter, and the microlenses are overlapping but do not cover an entire area of the array of color pixels.

28. The microdisplay of claim 27, wherein the spacer layer has a height that is within 10% of a height of the microlenses.

29. The microdisplay of claim 27, further comprising: driver circuitry that controls a brightness and color of the color pixels.
